(19) United States
(12) Patent Application Publication
(10) Pub. No.: US 2015/0047559 A1
(43) Pub. Date: Feb. 19, 2015

(54) SUSCEPTOR AND WAFER HOLDER

(71) Applicant: LG INNOTEK CO., LTD., Seoul (KR)

(72) Inventor: Ick Chan Kim, Seoul (KR)

(21) Appl. No.: 14/387,156

(22) PCT Filed: Mar. 21, 2013
(86) PCT No.: PCT/KR2013/002370

§ 371 Date: Sep. 22, 2014

(30) Foreign Application Priority Data
Mar. 21, 2012 (KR) 10-2012-0028750

(51) Int. Cl. C23C 16/458

(52) U.S. Cl. CPC C23C 16/4581; C23C 16/4582
USPC 118/500

(57) ABSTRACT

Disclosed is a susceptor. The susceptor comprises a susceptor bottom plate supporting a wafer holder; a susceptor top plate opposite to a susceptor bottom plate; and susceptor lateral-side plates extending from the susceptor bottom plate to the susceptor top plate, and wherein at least one of the susceptor top plate, the susceptor bottom plate, and the susceptor lateral-side plates includes the adiabatic layer.

### TECHNICAL FIELD

The embodiment relates to a susceptor and a wafer holder.

### BACKGROUND ART

In general, among technologies to form various thin films on a substrate or a wafer, a CVD (Chemical Vapor Deposition) scheme has been extensively used. The CVD scheme results in a chemical reaction. According to the CVD scheme, a semiconductor thin film or an insulating layer is formed on a wafer surface by using the chemical reaction of a source material.

The CVD scheme and the CVD device have been spotlighted as an important thin film forming technology due to the fineness of the semiconductor device and the development of high-power and high-efficiency LED. Recently, the CVD scheme has been used to deposit various thin films, such as a silicon layer, an oxide layer, a silicon nitride layer, a silicon oxynitride layer, or a tungsten layer, on a wafer. In order to reduce the fabrication cost, a wafer having a large diameter has been steadily studied and researched.

However, according to the CVD scheme that is currently in use, the internal temperature of a susceptor receiving a substrate or a wafer formed thereon with a thin film may be irregularly distributed. In other words, the temperature of the whole inner portion of the susceptor received in a reaction chamber and heated by an external heating member may be irregular. Accordingly, the substrate or the wafer received in the susceptor may be deposited thereon with a thin film having irregular thickness and irregular concentration.

Therefore, in order to deposit a thin film having a uniform thickness on a substrate or a wafer, the necessity for a susceptor having uniform temperature distribution is raised.

### DISCLOSURE OF INVENTION

### Technical Problem

The embodiment provides a susceptor capable of uniformly maintaining the internal temperature of a susceptor when depositing a thin film on a substrate or a wafer.

### Solution to Problem

According to the embodiment, there is provided a susceptor. The susceptor comprises a susceptor bottom plate supporting a wafer holder; a susceptor top plate opposite to a susceptor bottom plate; and susceptor lateral-side plates extending from the susceptor bottom plate to the susceptor top plate, and wherein at least one of the susceptor top plate, the susceptor bottom plate, and the susceptor lateral-side plates includes the adiabatic layer.

### Advantageous Effects of Invention

As described above, according to the susceptor and the wafer holder of the embodiment, the adiabatic layer can be coated on the susceptor and/or the wafer holder. In other words, the adiabatic layer can be coated on at least one surface of the susceptor and/or the wafer holder.

In addition, the adiabatic layer is formed by alternately stacking the first and second adiabatic layers, which include a tantalum carbide (TaC) layer, a hafnium nitride (HtN) layer, a silicon carbide layer (SiC) layer, an aluminum nitride (AlN) layer, a titanium nitride (TiN) layer, or a tantalum nitride (TaN) layer, on each other.

In addition, the adiabatic layer can reduce the moving path of electrons or phonons in the adiabatic layer, that is, a mean free path of the electrons or phonons. In addition, the phonon scattering caused by the interface between the first and second adiabatic layers can be increased in the adiabatic layer, and the increased phonon scattering can reduce the mean free path of the electrons or the phonons. Accordingly, the temperature of the whole inner portion of the susceptor can be uniformly maintained.

Accordingly, since the internal temperature of the susceptor can be uniformly maintained, the SiC thin film can be stably grown from the substrate or the wafer, and the high-quality SiC epi-wafer can be fabricated.

### BRIEF DESCRIPTION OF DRAWINGS

FIG. 1 is a view showing a deposition apparatus according to the embodiment.

FIG. 2 is a sectional view showing a layered structure of an adiabatic layer according to the embodiment.

FIG. 3 is a sectional view showing a layered structure of an adiabatic layer according to another embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

Since the size of each layer (film), region, pattern, or structure shown in the drawings may modified for the purpose of convenience or clarity, the size of each layer (film), region, pattern, or structure does not utterly reflect an actual size.

Hereinafter, the embodiment will be described in detail with reference to accompanying drawings.

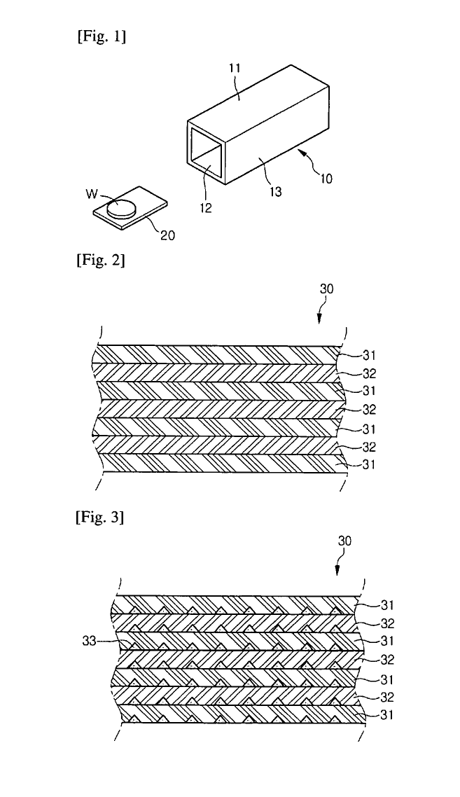

FIG. 1 is a view showing a deposition apparatus according to the embodiment

Referring to FIG. 1, the deposition apparatus according to the embodiment includes a susceptor 10 and a wafer holder 20 received in the susceptor 10. The susceptor 10 and/or the wafer holder 20 include an adiabatic layer 30.

The susceptor 10 may include a scepter bottom plate 12 supporting the wafer holder 20, a susceptor top plate 11 directly opposite to the susceptor bottom plate 12, and susceptor lateral-side plates extending from the susceptor bottom plate 12 to the susceptor top plate 11. In other words, the susceptor 10 may have the shape of a rectangular parallelepiped in which the susceptor top plate 11 mutually faces the scepter bottom plate 12, and the susceptor top plate 11 is connected to the susceptor bottom plate 12 through the susceptor lateral plates 13 extending from the susceptor bottom plate 12 to the susceptor top plate 11.

The susceptor 10 may include graphite easily machined and representing superior heat resistance so that the susceptor 10 can endure a high-temperature environment. In addition, the susceptor 10 may have the structure in which the adiabatic layer 30 is coated on a graphite body. In other words, the susceptor 10 may have the structure in which the susceptor top plate 11, the susceptor bottom plate 12, and the susceptor lateral-side plates 13 include graphite, and the adiabatic layer 30 is coated on the graphite. Preferably, the susceptor 10 may have the structure in which the adiabatic layer 30 is coated on at least one of the susceptor top plate 11, the susceptor bottom plate 12, and the susceptor lateral-side plates 13.

The adiabatic layer 30 may be coated on an inner portion or an outer portion of the susceptor 10. Preferably, the adiabatic layer 30 may be coated on the outer portion of the susceptor 10. More preferably, the adiabatic layer 30 may be coated on the outer portion of at least one of the susceptor top plate 11, the susceptor bottom plate 12, and the susceptor lateral-side plates 13.

The adiabatic layer 30 uniformly maintains the internal temperature of the susceptor 10. The details of the adiabatic layer 30 will be described in detail later with reference to accompanying drawings.

Reactive gas may be introduced into the susceptor 10. Preferably, the reactive gas may include carbon (C) and silicon (Si). For example, the reactive gas may include silane (SiH₄) and ethylene (C₂H₄), or may include silane (SiH₄) and propane (C₃H₈). However, the embodiment is not limited thereto, and the reactive gas may include various reactive gases including C and Si.

The susceptor 10 may be directly or indirectly heated by a heating member (not shown) which is positioned at the outside of the susceptor and includes an induction coil or a resistance heating member, so that the susceptor 10 is heated until a thin film growth temperature comes. If the internal temperature of the susceptor 10 is raised to the thin film growth temperature, the substrate or the wafer received in the susceptor 10 may react with the reactive gas, so that a silicon carbide (SiC) thin film may be deposited on the substrate or the wafer.

The wafer holder 20 may be received in the susceptor 10. Preferably, the wafer holder 20 may be provided at the rear portion of the susceptor 10 on the basis of the direction in which the reactive gas flows in the susceptor 10. The wafer holder 20 supports the substrate or the wafer W. The wafer holder 20 may include silicon carbide (SiC), or graphite. In addition, the adiabatic layer 30 may be coated on a SiC layer or a graphite layer. Preferably, the adiabatic layer 30 may be coated on the top surface of the wafer holder 20. The adiabatic layer 30 may be coated on the top surface of the wafer holder 20, so that the temperature of the substrate or the wafer supported on the wafer holder may be uniformly maintained.

Hereinafter, the adiabatic layer 30 according to the embodiment will be described with reference to FIGS. 2 and 3.

FIG. 2 is a sectional view showing a layered structure of the adiabatic layer 30 according to the embodiment, and FIG. 3 is a sectional view showing the layered structure of the adiabatic layer 30 according to another embodiment.

Referring to FIGS. 2 and 3, the adiabatic layer 30 according to the embodiment includes first and second adiabatic layers 31 and 32. Preferably, the adiabatic layer 30 may include a plurality of first adiabatic layers 31 and a plurality of second adiabatic layers 32. The first and second adiabatic layers 31 and 32 may be alternately stacked on each other. In other words, the adiabatic layer 30 may have the structure in which each of the first adiabatic layers 31 and each of the second adiabatic layers 32 are alternately stacked on each other.

The first adiabatic layer 31 or the second adiabatic layer 32 may include a tantalum carbide (TaC) layer, a hafnium nitride (HfN) layer, a silicon carbide layer (SiC) layer, an aluminum nitride (AlN) layer, a titanium nitride (TiN) layer, or a tantalum nitride (TaN) layer. In other words, the first adiabatic layer 31 or the second adiabatic layer 32 may include at least one of the TaC layer, the HfN layer, the SiC layer, the AlN layer, the TiN layer, and the TaN layer. The layers constituting the first adiabatic layer 31 may be different from the layers constituting the second adiabatic layer 32. The layers constituting the first and second adiabatic layers 31 and 32 are alternately formed with each other, thereby forming the final adiabatic layer 30.

The first adiabatic layer 31 may have the thickness of about 2 nm to about 50 nm. In addition, the second adiabatic layer 32 may have the thickness of about 2 nm to about 50 nm. In addition, the thickness of the adiabatic layer 30 formed by alternately stacking the first adiabatic layers 31 and the second adiabatic layers 32 on each other may be in the range of about 500 nm to about 100 μm. If the thickness of the adiabatic layer 30 is less than 500 nm, the adiabatic efficiency may be lowered, so that heat loss may occur in the susceptor 10. If the thickness of the adiabatic layer 30 may exceed 100 μm, the coating on the susceptor 10 is impossible, so that the adiabatic layer 30 may have disadvantages in terms of efficiency and cost.

In addition, as shown in FIG. 3, the first adiabatic layer 31 or the second adiabatic layer 32 may have nano-dot patterns 33. The nano-dot patterns 33 may be formed in nano-size, and may include at least one of TaC, HfN, SiC, AlN, TiN, and TaN.

The nano-dot patterns 33 may have the shape of a triangle, a rectangle, a sphere, or an oval. However, the embodiment is not limited thereto, and the nano-dot patterns 33 may have various shapes. In addition, the nano-dot patterns 33 may have various shapes at a uniform interval or an irregular interval.

The nano-dot patterns 33 may be formed at one of the first adiabatic layer 31 and the second adiabatic layer 32, or may be formed at both of the first and second adiabatic layers 31 and 32. In addition, the nano-dot patterns 33 may be formed at a uniform interval. In addition, the nano-dot patterns 33 may be formed in various shapes at the first adiabatic layer 31 and/or the second adiabatic layer 32.

The adiabatic layer 30 including the first adiabatic layer 31 or the second adiabatic layer 32 may have the thermal conductivity of about 10 W/mK or less. Preferably, the adiabatic layer 30 may have the thermal conductivity of about 2 W/mK or less. In general, the thermal conductivity of a material refers to the intrinsic constant of the material. However, if the material is coated or deposited in nano-size, an individual nano-size material may have the thermal conductivity significantly lower than that of a bulk material before a cutting process. Accordingly, the first adiabatic layer 31 or the second adiabatic layer 32 may have the thermal conductivity lower than that of the nano-dot pattern 33.

In addition, the first and second adiabatic layers 31 and 32 may reduce a mean free path of electrons or phonons moving in the adiabatic layer 30. Since the mean free path is proportional to the thermal conductivity, the reduction of the mean free path may reduce the thermal conductivity.

In other words, the nano-dot patterns 33 increase the phonon scattering caused by the interface between the first and second adiabatic layers 31 and 32 in the adiabatic layer 30, and the increased phonon scattering reduces the mean free path of electrons or phonons, thereby reducing the thermal conductivity. The adiabatic layer 30 may be coated on one of the susceptor top plate 11, the susceptor bottom plate 12, and the susceptor lateral-side plates 13, or may be coated on the top surface of the wafer holder 20, thereby preventing the hest loss at the outer portion of the susceptor, uniformly maintaining the temperature of the whole inner portion of the susceptor, and preventing the heat loss of the wafer holder 20 supporting the substrate or the wafer.

In addition, the nano-dot patterns 33 may more increase the scattering of the electrons or the phonons, so that the mean free path of the electrons or the phonons may be more reduced, thereby more improving the adiabatic efficiency.

Accordingly, the thermal conductivity of the adiabatic layer 30 may be significantly lowered. In other words, the adiabatic layer 30 formed by alternately stacking the first and second adiabatic layers 31 and 32 having nano-size on each other may have significantly low thermal conductivity. Accordingly, the susceptor 10 coated with the adiabatic layer can prevent the heat loss in the susceptor 10, and the temperature of the whole inner portion of the susceptor 10 can be uniformly maintained.

Accordingly, since the internal temperature of the susceptor 10 can be uniformly maintained, the SiC thin film can be stably grown from the substrate or the wafer, and the high-quality SiC epi-wafer can be fabricated. In addition, the electrical characteristic of a device employing the epi-wafer can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic are described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. The susceptor comprises:
a susceptor bottom plate supporting a wafer holder;
a susceptor top plate opposite to a susceptor bottom plate; and
susceptor lateral-side plates extending from the susceptor bottom plate to the susceptor top plate, and
wherein at least one of the susceptor top plate, the susceptor bottom plate, and the susceptor lateral-side plates includes the adiabatic layer.

2. The susceptor of claim 1, wherein the adiabatic layer includes a plurality of first adiabatic layers and a plurality of second adiabatic layers.

3. The susceptor of claim 2, wherein the first adiabatic layers or the second adiabatic layers include at least one of a tantalum carbide (TaC) layer, a hafnium nitride (HfN) layer, a silicon carbide layer (SiC) layer, an aluminum nitride (AlN) layer, a titanium nitride (TiN) layer, and a tantalum nitride (TaN) layer.

4. The susceptor of claim 3, wherein each of the first adiabatic layers or the second adiabatic layers has a thickness in a range of about 2 nm to about 50 nm.

5. The susceptor of claim 1, wherein the adiabatic layer has a thickness in a range of about 500 nm to about 100 μm.

6. The susceptor of claim 3, wherein nano-dot patterns are Ruined at the first adiabatic layers or the second adiabatic layers.

7. The susceptor of claim 5, wherein the nano-dot patterns include at least one of tantalum carbide (TaC), hafnium nitride (HfN), silicon carbide layer (SiC), aluminum nitride (AlN), titanium nitride (TiN), and tantalum nitride (TaN).

8. A wafer holder comprising;
a adiabatic layer includes a plurality of first adiabatic layers and a plurality of second adiabatic layers.

9. The wafer holder of claim 8, wherein the first adiabatic layers or the second adiabatic layers include at least one of a tantalum carbide (TaC) layer, a hafnium nitride (HfN) layer, a silicon carbide layer (SiC) layer, an aluminum nitride (AlN) layer, a titanium nitride (TiN) layer, and a tantalum nitride (TaN) layer.

10. The wafer holder of claim 9, wherein each of the first adiabatic layers or the second adiabatic layers has a thickness in a range of about 2 nm to about 50 nm.

11. The wafer holder of claim 9, wherein nano-dot patterns are formed at the first adiabatic layers or the second adiabatic layers.

12. The wafer holder of claim 11, wherein the nano-dot patterns include at least one of tantalum carbide (TaC), hafnium nitride (HfN), silicon carbide layer (SiC), aluminum nitride (AlN), titanium nitride (TiN), and tantalum nitride (TaN).

13. The wafer holder of claim 9, wherein the adiabatic layer has a thickness in a range of about 500 nm to about 100 μm.
